(19) United States
(12) Patent Application Publication
(10) Pub. No.: US 2025/0330169 A1
(43) Pub. Date: Oct. 23, 2025

(54) TRANSISTOR CONTROL CIRCUIT

(71) Applicant: STMicroelectronics International N.V., Geneva (CH)

(72) Inventors: Julio BRANDELERO, Toulouse (FR); Matthieu GAYCHET, Castanet-Tolosan (FR); Mickael ROUCH, MONTGISCARD (FR)

(21) Appl. No.: 19/169,364

(22) Filed: Apr. 3, 2025

(30) Foreign Application Priority Data
Apr. 17, 2024 (FR) FR2403980

(51) Int. Cl. H03K 17/0812

(52) U.S. Cl. CPC H03K 17/08122

(57) ABSTRACT

A control circuit for a transistor is provided. An example control circuit is configured to be coupled to a transistor and to lower a voltage applied to the gate of the transistor when a current delivered to the gate is higher than a first threshold for a first time period.

### CROSS REFERENCE TO RELATED APPLICATION(S)

This application claims the priority benefit of French patent application number FR2403980, filed on Apr. 17, 2024, entitled “Circuit de commande d'un transistor”, which is hereby incorporated by reference to the maximum extent allowable by law.

### TECHNICAL FIELD

The present disclosure generally concerns transistor control circuits as well as the corresponding methods.

### BACKGROUND

When a transistor, particularly a power transistor, undergoes a short-circuit, it may be damaged. Certain standards require for transistors to remain viable, at least for a minimum time period, when a short-circuit occurs.

### BRIEF SUMMARY

There exists a need to protect transistors, particularly power transistors, on occurrence of a short-circuit while respecting certain standards.

An embodiment overcomes all or part of the disadvantages of known circuits.

An embodiment provides a control circuit for a transistor, configured to be coupled to a transistor and to lower a voltage applied to the gate of the transistor when a current delivered to the gate is higher than a first threshold for a first time period.

An embodiment provides a transistor control method comprising the lowering of a voltage applied to the gate of the transistor by a control circuit of the transistor when a current delivered to the gate is higher than a first threshold for a first time period.

According to an embodiment, the control circuit is configured to keep the voltage applied to the gate lowered for a second time period.

According to an embodiment, the voltage applied to the gate of the transistor is lowered so that the transistor changes conduction state.

According to an embodiment, the first threshold is greater than or equal to 100 μA.

According to an embodiment, the first threshold is greater than or equal to 400 μA.

According to an embodiment, the first time period is equal to or greater than 100 nanoseconds.

According to an embodiment, the second time period is equal to or greater than 200 nanoseconds.

According to an embodiment, the control circuit (102) comprises:
a first and a second nodes of application of a control voltage, the second node of application of a control voltage being configured to be coupled to the source of the transistor;
a high-pass filter coupling the first node of application of a control voltage to a first terminal of a first switch having a second terminal coupled to an output node of the control circuit, the output node being configured to be coupled to the gate of the transistor; and
a second switch coupling the output node to the second node of application of a control voltage, the first and second switches being configured to be controlled by complementary signals.

According to an embodiment, the control circuit comprises a second capacitive element coupling the first node and the second node of application of a control voltage.

According to an embodiment, the control circuit comprises:
a first and a second nodes of application of a control voltage, the second node of application of a control voltage being configured to be coupled to the source of the transistor;
a low-pass circuit between the first node of application of a control voltage and a third node coupled to a first terminal of a first switch,
   a second terminal of the first switch being coupled to an output node of the control circuit configured to be coupled to the gate of the transistor;
a Zener diode coupling the third node to the second node of application of a control voltage; and
a second switch coupling the output node to the second node of application of a control voltage, the first and second switches being configured to be in a conduction state opposite to each other.

According to an embodiment, the low-pass circuit comprises:
a resistor coupling the first node of application of a control voltage and the third node; and
a capacitive element coupling the third node and the second node of application of a control voltage.

According to an embodiment, the control circuit comprises a high-pass circuit coupling the third node to the first terminal of the first switch.

According to an embodiment, the high-pass circuit is formed of a resistor in parallel with a capacitive element.

According to an embodiment, the second terminal of the first switch is coupled to the output node of the control circuit via a resistor.

An embodiment provides a control device comprising at least one control circuit as disclosed and at least one transistor so that the control circuit is coupled to the gate of the transistor.

According to an embodiment, the transistor is a high electron mobility transistor.

According to an embodiment, the transistor is based on a GaN alloy.

An embodiment provides a system comprising a motor and at least one device as disclosed.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 very schematically shows in the form of blocks an example of a system to which the embodiments apply;

FIG. 2 shows a timing diagram of the operation of the system of FIG. 1;

FIG. 3 shows an embodiment of a block of FIG. 1;

FIG. 4 shows an embodiment of a block of FIG. 3;

FIG. 5 shows an embodiment of a block of FIG. 3;

FIG. 6 shows an embodiment of a block of FIG. 3;

FIG. 7 shows a timing diagram of the operation of the block of FIG. 4;

FIG. 8 shows a timing diagram of the operation of the block of FIG. 5; and

FIG. 9 shows an embodiment of the system of FIG. 1.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

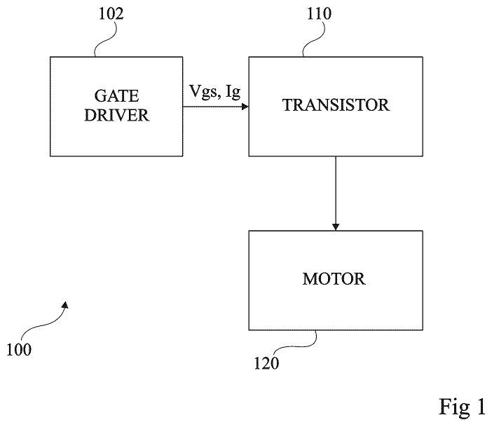

FIG. 1 very schematically shows in the form of blocks an example of a system 100 to which the embodiments apply.

System 100 for example comprises one or a plurality of transistors 110 (TRANSISTOR) which are controlled by one or a plurality of control circuits 102 (GATE DRIVER). The one or a plurality of transistors 110 for example control the power supply of an object such as a motor 120 (MOTOR).

The control circuit controls the conduction state (on or off) of transistors 110 by varying a voltage Vgs applied between the gate and the source of the transistors.

Transistors 110 are for example characterized by a gate current Ig which may flow through the gate. In other words, a gate current is a current delivered to the gate by the control circuit and which is due to leakages between the gate and the source, for example, on application of voltage Vgs.

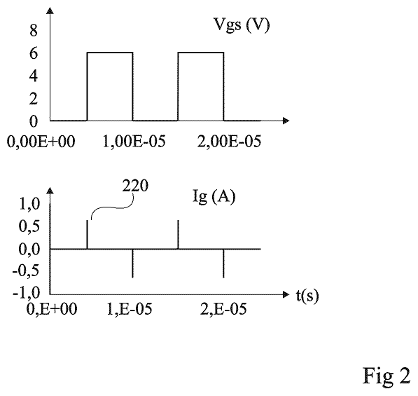

FIG. 2 shows a timing diagram of the operation of the system of FIG. 1.

More particularly, FIG. 2 shows the voltage Vgs applied to the gate of the one or a plurality of transistors as a function of time t, indicated in seconds, as well as the corresponding current Ig, called gate current or leakage current, necessary to charge or discharge the gate voltage.

In the shown example, voltage Vgs is in the form of square pulses and for example alternates every 10 μs between a high level which is for example held at 6 V for 5 μs and a low level which is for example held at 0 V (or a negative voltage) for 5 μs. When voltage Vgs switches from the low level to the high level, a peak 220 of current Ig occurs for a few nanoseconds, for example five nanoseconds, at 0.6 A. The same occurs when voltage Vgs switches from the high level to the low level, but with a gate current of opposite direction. These current peaks 220 form part of the system operation and it may be advantageous to keep them.

Standards, for example in the automobile world, impose for control transistors to remain viable even while being submitted for 10 μs to at least 60% of the maximum admissible drain-source voltage. To perform this type of test, a 400-V voltage is for example applied to the transistor 110 in the off state, which is assembled in parallel with a capacitive element. Then, a short-circuit is created by applying an adequate voltage Vgs to turn on the transistor, for example 6 V. The high energy stored in the capacitive element then very rapidly discharges into the transistor. This enables to replicate a short-circuit for example occurring in the object, such as the motor, which is controlled with transistor 110.

Different solutions are envisaged to ensure the robustness of transistors against short-circuits occurring in real conditions or those generated for standards.

A first solution is to increase the on-state resistivity (Ron measured in Ω.cm²) of the transistor. However, this alters the other performances of the circuit. This solution is also expensive in terms of development time and adversely affects the efficiency of the transistor in a normal operation period.

A second solution comprises detecting the short-circuit and then protecting the transistor. One should then use a very high speed sensor, which has to measure the voltage through transistor after the change of conduction state of the transistor or to measure the current, and then use a feedback circuit to turn off the transistor.

The second solution requires a measurement according to a very large bandwidth with very fast response times to avoid the destruction of the transistor.

To overcome these disadvantages, the embodiments provide for the control circuit of the transistor to be configured to lower the voltage applied to the gate Vgs of the transistor when current Ig, that is, the gate current, delivered to the gate, is higher than a first threshold for a first time period.

The embodiments advantageously use the fact that when the temperature rapidly increases, which is the case during a short-circuit, gate current Ig increases. In power applications, the transistors used are for example high electron mobility transistors (HEMT), manufactured based on GaN and/or GaN alloys. For this type of transistors, the gate current may pass from a value lower than 600 μA for temperature ranges lower than 150° C. to values of more than 100 mA for higher temperatures reached during short-circuits.

Determining that the current delivered to the gate is higher than a first threshold for a first time period corresponds to determining that the current delivered to the gate is higher than a first threshold for a first continuous time period. In other words, in order to detect a short circuit and thereafter act on the gate voltage, the current delivered to the gate has to be higher than the first threshold continuously during the first period of time.

Further, the condition according to which the gate current has to be greater than the first threshold during the first time period enables to avoid lowering the voltage applied to the gate when current peaks 220 occur.

The control circuit can then turn off the transistor when the gate current increases, which avoids the for temperature to further increase during a short-circuit. The short-circuit current which flows between the drain and the source of the transistor is thus stopped, which avoids damaging the transistor.

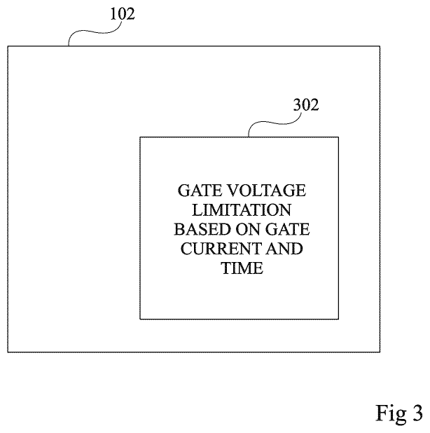

FIG. 3 shows an embodiment of the system of FIG. 1. More particularly, FIG. 3 shows an example of control circuit 102.

The shown example of control circuit 102 for example applies to the control of a transistor 110 having its gate current substantially varying (for example by in the order of or more than 1 μA/° C.) with temperature. In an example, control circuit 102 is configured to control one or a plurality of transistors of high electron mobility type and/or based on GaN and/or on GaN alloys. In an example, the one or a plurality of transistors comprise a GaN and AlGaN junction, which forms a two-dimensional electron gas. High electron mobility transistors are blocked for gate-source voltages lower than a threshold.

In the shown example, the control circuit comprises one or a plurality of circuits 302 (GATE VOLTAGE LIMITATION BASED ON GATE CURRENT AND TIME) configured to lower the voltage applied to the transistor gate Vgs when the gate current Ig delivered to the transistor gate is higher than a first threshold for a first time period.

In an example, the first threshold is equal to or greater than 100 μA or more particularly equal to or greater than 400 μA.

In another example, the first time period is equal to or greater than 100 ns, more particularly equal to or greater than 200 ns.

If a current peak 220 occurs, the gate voltage is not lowered, since the peak has a duration shorter than the first time period, which enables to ensure a normal operation of the circuit outside of short-circuit conditions.

During a short-circuit, the transistor temperature drastically increases within a few tens of nanoseconds, which increases the gate current in return. If the gate current exceeds the first threshold for the entire first time period, then the gate voltage is for example lowered to the gate voltage saturation value. The transistor then for example changes conduction state, which protects it.

In an example, control circuit 102 is configured to keep the gate voltage lowered to a low level, for example to a level where the conduction state of the transistor is non-conductive, and this, for a second time period. This for example enables the situation having caused the short-circuit to disappear before the transistor resumes a standard operation.

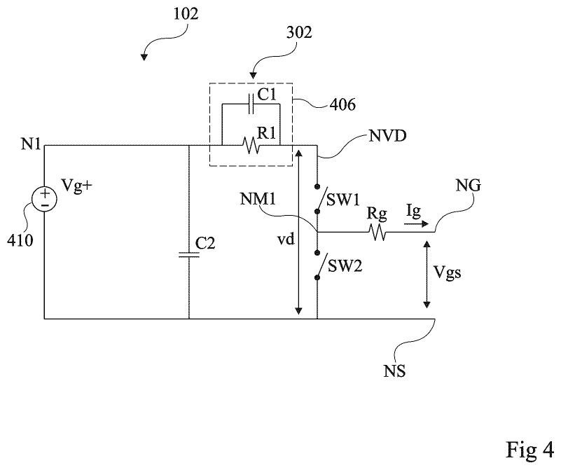

FIG. 4 shows an embodiment of a block of FIG. 3. More particularly, FIG. 4 shows an example of control circuit 102.

In the shown example, control circuit 102 comprises an electric power source 410 applying a control voltage Vg+ between a node N1 and a node NS. Node NS is configured to be coupled, preferably connected, to the source of the transistor 110 to be controlled.

In the shown example, control circuit 102 further comprises a high-pass circuit 406, in other words a high-pass filter, coupling node N1 to a first terminal NVD of a first switch SW1. A second terminal NM1 of first switch SW1 is coupled to an output node NG of control circuit 102 via a resistor Rg. Output node NG is configured to be coupled to the gate of the transistor 110 to be controlled.

In the shown example, control circuit 102 comprises a second switch SW2 coupling node NG to node NS. In an example, the first and second switches are configured to be in a conduction state opposite to each other. In another example, switch SW1 is an NMOS transistor and transistor SW2 is a PMOS transistor. In an example, switch SW1 is a PMOS transistor and transistor SW2 is an NMOS transistor. The control signals of these two switches are for example opposite by using for example an inverter circuit on one of the switch control signals IN. The circuit formed by the two switches is a circuit of “push-pull” type, which enables to amplify for example and to create a square signal between nodes NG and NS.

In the shown example, control circuit 102 further comprises an optional second capacitive element C2, coupling node N1 and node NS. In this example, the role of capacitive element C2 is to supply the current peaks 220.

In an example, high-pass filter 406 is formed by a capacitive element C1 in parallel with a resistor R1 between nodes NVD and N1.

In an example, resistor R1 for example has a value in the order of some ten Ohms, C2 is in the order of one μF, and C1 in the order of some ten nF.

In operation, current peaks 220 are in the order of a few nanoseconds, which corresponds to frequencies greater than or equal to 10 MHz, for example. These current peaks will circulate through high-pass filter 406 from capacitive element C1, and optionally also from capacitive element C2, and not or only slightly through R1, which will create a low-impedance path. The gate current due to the short-circuit, and delivered to the gate from electric power source 410, is not in the form of peaks and thus corresponds to lower frequencies, in the order of a few hundreds of kHz. This gate current will flow through C1 and additionally R1, which forms a path of higher impedance, which attenuates the voltage Vg+ delivered by electric power source 410. The voltage Vgs delivered to the gate it thus automatically attenuated, for example to fall under the conduction threshold of the transistor.

In the shown example, the values of C1, and possibly C2, and R1 will be selected to avoid attenuating frequencies higher than 10 MHz and to attenuate frequencies in the order of a few hundred kHz. The higher the value of R1, the higher the voltage drop applied to the transistor gate during a short-circuit will be.

The example of FIG. 4 enables the gate voltage to be automatically lowered when the gate current exceeds the first threshold during the first time period, without requiring a measurement or a feedback loop. This increases the speed enabling to protect the transistor and lowers the implementation cost while limiting the impact on the performance.

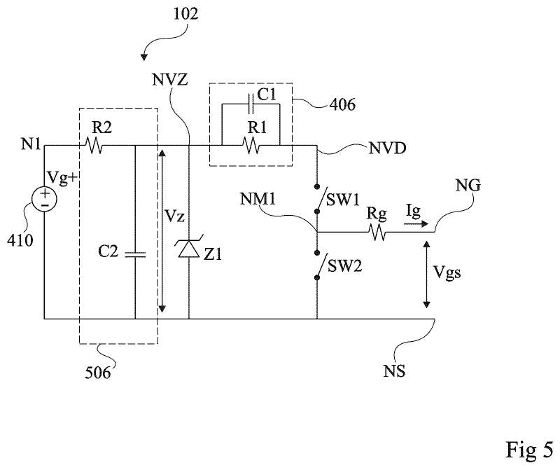

FIG. 5 shows an embodiment of a block of FIG. 3. More particularly, FIG. 5 shows an example of control circuit 102.

In the shown example, control circuit 102 comprises power source 410 as well as nodes N1, NS which are similar to those of FIG. 4. The two switches SW1 and SW2, as well as resistor Rg, are also similar to those of FIG. 4. Control circuit 102 further comprises a low-pass circuit 506, in other words a low-pass filter, between node N1 and a node NVZ coupled to the first terminal of first switch SW1. Control circuit 102 also comprises a Zener diode Z1 coupling node NVZ to node NS with the cathode of diode 21 facing node NVZ. In the shown example, low-pass filter 506 is implemented with a resistor R2, which couples node N1 and node NVZ; and with capacitive element C2, which this time couples node NVZ and node NS.

In the example of FIG. 5, high-pass filter 406 is optional and it may be implemented, in an example, between node NVZ and node NVD.

In an example of FIG. 5, capacitance C2 is in the order of 100 nF, capacitance C1 is approximately 10 nF, resistance R1 approximately 10 Ohms and R2 approximately 500 Ohms.

In operation, the low-pass filter slowly charges capacitive element C2 through resistor R2. Since Zener diode Z1 is present in antiparallel with capacitive element C2, resistor R2 may be chosen to be sufficiently high, in the order of several hundred Ohms, to ensure a normal operating state. During a short-circuit, the operation is similar to that of FIG. 4 except that voltage Vgs is kept below a low level, for example below the conduction threshold of the transistor, for a time period longer than 10 μs for example, which enables not to reset the short-circuit too rapidly. This also enables to leave time to notify a control unit of motor for example coupled, preferably connected, to the transistor.

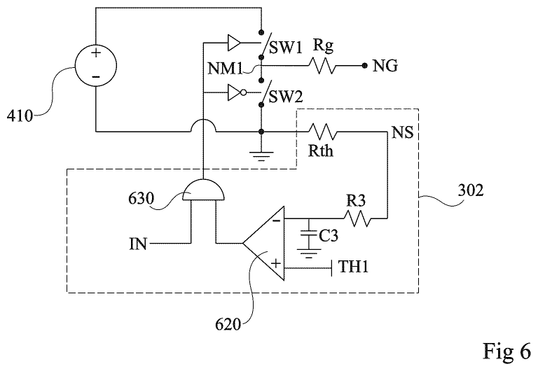

FIG. 6 shows an embodiment of a block of FIG. 3. More particularly, FIG. 6 represents an example of the control circuit 102.

In the represented example, the control circuit 102 comprises a power source 410 which is similar to the one of FIG. 4. The power source is referenced to local ground. Node NS is, in this example, coupled to local ground, via a measure resistance Rth. Both switches SW1 and SW2 as well as resistance Rg are also similar to the one of FIG. 4. In the illustrated example, switch SW1 is directly connected to the power source.

In the represented example, the voltage limiter circuit 302 further comprises the measure resistance Rth, and a low-pass circuit referenced to ground, otherwise the a low-pass filter, between node NS and a negative input, noted “−” of a comparator 620. The low-pass circuit is, in the represented example, formed with a resistance R3 coupling node NS to the input “−” of the comparator 620, and with a capacitance C3 coupling the input “−” of the comparator 620 to ground. A positive input, noted “+”, is coupled to a voltage rail configured to receive a threshold voltage TH1. The comparator output is coupled to an input of a “AND” type logic gate 630. Another input of the logic date 630 is configured to receive a control signal IN of the control circuit 102. The control signals of the switches SW1 and SW2 are inverted one to the other and are issued from a signal present at the logic gate 630 output.

In operation, the measure resistance Rth transforms the gate current Ig in a voltage which is proportional to the resistance Rth. The low-pass filter, composed of R3 and C3, loads slowly the capacitance C3 through the resistance R3. In case of peak currents 220, the negative voltage of the comparator does not reach the level of the imposed threshold voltage TH1 and the comparator 620 imposes the logic level 0 to the logic gate “AND” 630 which engages switch SW2 and impose a null voltage Vgs which stops the short-circuit current.

In an example, the Rth value is of about 2 Ω, R3 is of about 50 Ω, C1 of about 1 nF, and the threshold voltage TH1 of about 0,1V.

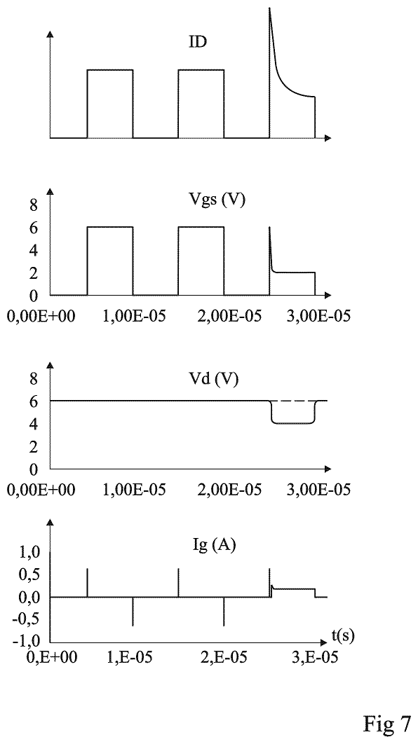

FIG. 7 shows a timing diagram of the operation of the block of FIG. 4. More particularly, FIG. 6 shows voltage Vgs, a voltage Vd between node NVD and node NS, gate current Ig, and drain current ID going through the transistor drain, as a function of time t expressed in seconds.

The beginning of the example of FIG. 6 is similar to the operation of FIG. 2. Voltage Vgs follows square pulses between approximately 6 V and a low level at 0 V or negative, for example. At each transition from one level to another, a current peak 220 occurs.

At the beginning of the third square pulse, at approximately 25 μs, a short-circuit occurs, for example due to too high a current drawn by a motor coupled, preferably connected, to the transistor. The transistor drain current ID increases, during the short-circuit, out of the normal functioning zone of the transistor. The temperature further increases within the transistor, which increases the gate current which passes from a level close to zero to approximately 200 mA. As a response, control circuit 102 lowers voltage Vgs from 6 V to 2 V within a few hundreds of nanoseconds, for example 300 ns. Voltage Vd is also rapidly lowered from 6 to 4 V, which differs for example from the usual behavior of control circuits, which is shown by the dotted line and which maintain voltage Vd whatever the value of the gate current.

At the end of the third square pulse, towards 30 μs, the level of Vgs is taken down to the low level by the push-pull circuit and thus the transistor becomes non-conductive, the gate current returns to a low level, and voltage Vd returns to 6 V.

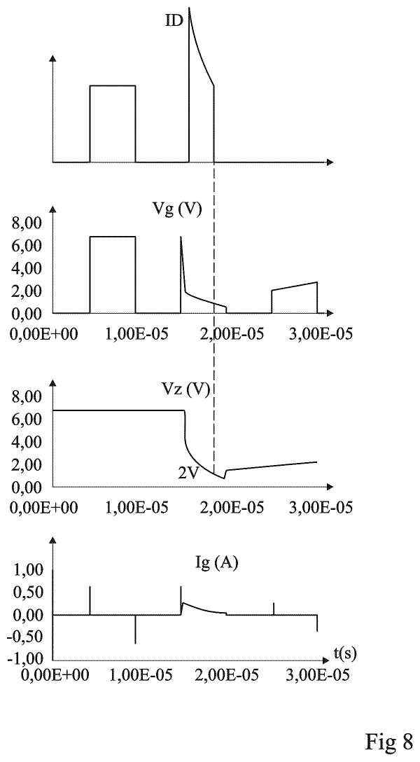

FIG. 8 shows a timing diagram of the operation of the block of FIG. 5.

More particularly, FIG. 7 shows voltage Vgs, a voltage Vz between node NVZ and node NS, gate current Ig, and drain current ID which goes through the transistor drain, as a function of time t expressed in seconds.

Between 0 and 15 μs, the example of FIG. 7 is similar to that of FIG. 2 or 6. When the second square pulse of Vgs passes from 0 to 6 V, at 15 μs, a short-circuit occurs (represented by an arrow). The drain current ID increases out of the normal functioning zone of the transistor. The gate current then very rapidly increases. In return, voltage Vz is lowered within less than some hundred nanoseconds from approximately 6 V to 4 V and then is lowered a little less rapidly to 2 V towards the end of the second square pulse around 20 μs. Voltage Vgs follows a same behavior, except that it lowers rapidly from 6 to 2 V and then slower to 0.5 V approximately until the end of the second square pulse. The drain current ID is fully blocked when the voltage Vgs is inferior to the conduction threshold of the transistor. The gate current also accordingly lowers.

From the end of the second square pulse at 20 μs, voltage Vz rises slowly, for example linearly.

Conversely to the example of FIG. 7, in the example of FIG. 8, voltage Vgs thus takes more time, for example 30 μs, before rising back above the level making transistor conductive, which creates a masking time that may last for one or a plurality of other square pulses.

The example de FIG. 8 enables to rapidly stop the short-circuit and allows the transmission of information relative to the presence of a short-circuit before enabling the transistor to be conductive again.

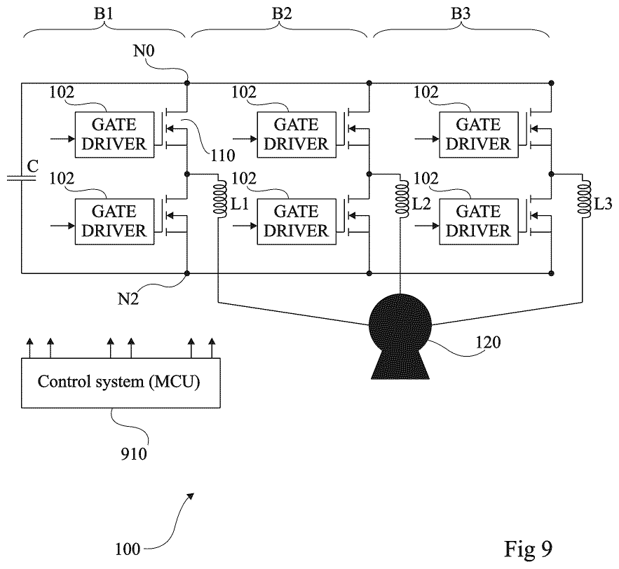

FIG. 9 shows an embodiment of the system of FIG. 1.

In the shown example, system 100 comprises a motor control circuit to control motor 120. The motor control circuit for example comprises a plurality of branches B1, B2, B3 coupled in parallel between a node N0 and a node N2. In this example, a capacitive element C also couples nodes N0 and N2.

In each branch, a first transistor has its drain coupled, preferably connected, to node N0 and its source coupled, preferably connected, to a node NM2, and a second transistor has its drain coupled, preferably connected, to node NM2 and its source coupled, preferably connected, to node N2.

Each of the transistors of each branch is controlled by a control circuit 102 such as that of FIG. 4 or 5. Each control circuit of a branch has its node NG coupled, preferably connected, to the gate of a transistor and its node NS coupled, preferably connected, to the source of the respective transistor.

In the shown example, the node NM2 of each branch B1, B2 or B3 is coupled, preferably connected, to a power supply phase of motor 120 via a smoothing inductance L1, L2, L3 respectively.

In the example of FIG. 9, system 100 also comprises a control unit 910 (Control system (MCU)) configured for example to generate the control signal of the switches SW1 and SW2 of each control circuit 102.

The system 100 of FIG. 8 enables to obtain motor control transistors which are more efficiently protected against short-circuits and which enable to comply with the standards.

The disclosed examples of control circuits may be applied for example in the automobile industry, in radio frequency application, radar systems, or microwave amplifiers, in audio amplifiers or radio frequency transmitters, as well as for the electrifying of vehicles, in particular electric and hybrid vehicles, or in lighting systems with light-emitting diodes for the management of currents and of voltages as well as for the improvement of the efficiency and of the performance.

Various embodiments and variants have been described. Those skilled in the art will understand that certain features of these various embodiments and variants may be combined, and other variants will occur to those skilled in the art. In particular, the values of resistors R1, R2, of capacitive elements C1 or C2 may be modified by those skilled in the art to allow a faster or slower lower of voltage Vgs after the detection of an increase in the gate current beyond a threshold for a given time period, as well as to modify the masking period.

Finally, the practical implementation of the described embodiments and variants is within the abilities of those skilled in the art based on the functional indications given hereabove. In particular, the described control circuits may be used to control different types of transistors other than transistors of HEMT type and/or based on GaN alloys, and particularly transistors having a gate current at the gate substantially varying along with temperature. Additionally, regarding the high-pass and low-pass filters, those skilled in the art may implement other implementations of these filters than those disclosed with resistors R1 and C1 or R2 and C2. Further, even though the examples given in the drawings for example apply to the case of a motor control, the described control circuit may be applied to other applications.

1. A control circuit for a transistor, wherein the control circuit is configured to be coupled to a transistor and to lower a voltage applied to a gate of the transistor when a current delivered to the gate is higher than a first threshold for a first time period.

2. The control circuit of claim 1, wherein the control circuit is configured to keep the voltage applied to the gate lowered for a second time period.

3. The control circuit of claim 1, wherein the voltage applied to the gate of the transistor is lowered so that the transistor changes conduction state.

4. The control circuit of claim 1, wherein the first threshold is greater than or equal to 100 μA.

5. The control circuit of claim 4, wherein the first threshold is greater than or equal to 400 μA.

6. The control circuit of claim 1, wherein the first time period is equal to or greater than 100 nanoseconds.

7. The control circuit of claim 2, wherein the second time period is equal to or greater than 200 nanoseconds.

8. The control circuit of claim 1, wherein the control circuit comprises:
a first node and a second node of application of a control voltage, the second node of application of a control voltage being configured to be coupled to a source of the transistor;
a high-pass filter coupling the first node of application of a control voltage to a first terminal of a first switch having a second terminal coupled to an output node of the control circuit, the output node being configured to be coupled to the gate of the transistor; and
a second switch coupling the output node to the second node of application of a control voltage, the first switch and the second switch being configured to be controlled by complementary signals.

9. The control circuit of claim 8, wherein the control circuit comprises a second capacitive element coupling the first node and the second node of application of a control voltage.

10. The control circuit of claim 1, wherein the control circuit comprises:
a first node and a second node of application of a control voltage, the second node of application of a control voltage being configured to be coupled to a source of the transistor;
a low-pass circuit between the first node of application of a control voltage and a third node coupled to a first terminal of a first switch, a second terminal of the first switch being coupled to an output node of the control circuit configured to be coupled to the gate of the transistor;
a Zener diode coupling the third node to the second node of application of a control voltage; and
a second switch coupling the output node to the second node of application of a control voltage, the first and second switches being configured to be in a conduction state opposite to each other.

11. The control circuit of claim 10, wherein the low-pass circuit comprises:
a resistor coupling the first node of application of a control voltage and the third node; and
a capacitive element coupling the third node and the second node of application of a control voltage.

12. The control circuit of claim 10, wherein the control circuit comprises a high-pass circuit coupling the third node to the first terminal of the first switch.

13. The control circuit of claim 12, wherein the high-pass circuit is formed of a resistor in parallel with a capacitive element.

14. The control circuit of claim 1, wherein a second terminal of a first switch is coupled to an output node of the control circuit via a resistor.

15. The control circuit of claim 1, where the current delivered to the gate is higher than a first threshold continuously for a first time period.

16. A control device comprising at least one of the control of claim 1 and at least one transistor so that the control circuit is coupled to the gate of the transistor.

17. The control device of claim 15 wherein the transistor is a high electron mobility transistor.

18. The control device of claim 15 wherein the transistor is based on a GaN alloy.

19. A system comprising a motor and at least one control device of claim 15, wherein the motor is controlled by the at least one device.

20. A transistor control method comprising:
lowering of a voltage applied to a gate of a transistor by a control circuit of the transistor when a current delivered to the gate is higher than a first threshold for a first time period.
